(19) United States
(12) Patent Application Publication
(10) Pub. No.: US 2005/0253790 A1
(43) Pub. Date: Nov. 17, 2005

(54) Display apparatus and image reading/displaying system incorporating the same

(75) Inventor: Hideki Uchida, Nara (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, OSAKA (JP)

(21) Appl. No.: 10/520,363

(22) PCT Filed: Jun. 23, 2003
(86) PCT No.: PCT/JP03/07907

§ 371 Date: Jan. 6, 2005

(30) Foreign Application Priority Data
Jul. 10, 2002 (JP) 2002-201549

(51) Int. Cl. G09G 3/30

(52) U.S. Cl. 345/76

(57) ABSTRACT

A display apparatus includes a display panel 110 including a light emitting device 120 for each of a plurality of pixels, and a light receiving device 130 provided on the display panel 110 for each of the plurality of pixels. The display panel 110 displays an image by using light output from the light emitting device 120 toward the panel front side. The light receiving device 130 receives a portion of light output from the light emitting device 120 toward the panel back side that is reflected by an irradiated object 10 located on the panel back side. Since the light used for displaying an image and the light used for reading an image are commonly output from the light emitting device 120, it is possible to display and read image information with a simple, thin and light-weight structure.

### TECHNICAL FIELD

The present invention relates to a display apparatus and an image reading/displaying system incorporating the same, and more particularly to a display apparatus including a light emitting device for each pixel and an image reading/displaying system incorporating the same.

### BACKGROUND ART

In recent years, image display apparatuses such as flat panel displays have been actively researched and developed. The performance of such image display apparatuses has been improved dramatically with larger screen sizes, a multi- or full-color display capability, a gray scale display capability, and a motion picture display capability.

While the performance of such image display apparatuses has been improved, there is a demand for display apparatuses having additional functions, in addition to the basic function of displaying an image, to further enhance the usefulness thereof

### DISCLOSURE OF THE INVENTION

The present invention has been made in view of the above, and has an object to provide a display apparatus capable of reading an image in addition to displaying an image, and an image reading/displaying system incorporating the same.

A display apparatus of the present invention includes: a display panel including a light emitting device for each of a plurality of pixels for displaying an image by using light that is output from the light emitting device toward a panel front side; and a light receiving device provided on the display panel for each of the plurality of pixels for receiving a portion of light output from the light emitting device toward a panel back side that is reflected by an irradiated object located on the panel back side. Thus, the object set forth above is realized.

The display panel may be an active matrix type display panel including a substrate and a light emission control section provided on the substrate for controlling light emission of the light emitting device, with the light emitting device and the light receiving device being provided on the substrate.

The display panel may include a color filter provided so as to overlap with at least a portion of a light receiving surface of the light receiving device.

The display panel may include a light blocking layer provided between the light emitting device and the light receiving device.

The display panel may include a light converging section provided on the panel back side of the light emitting device.

The light emitting device may include a light emitting layer containing light emitting molecules, and a pair of electrodes opposing each other via the light emitting layer therebetween.

One of the pair of electrodes that is provided on the panel back side may be made of a transparent conductive material.

One of the pair of electrodes that is provided on the panel back side may include an opening therein.

It is preferred that the light emitting molecules contained in the light emitting layer are oriented so as to be generally parallel to a surface of the display panel on the panel back side and generally perpendicular to a straight line between the opening and the light receiving device.

It is preferred that a light emitting portion of the light emitting layer is localized toward the electrode including the opening therein.

The light emitting device is, for example, an organic electroluminescent device.

The display panel may be flexible.

The display apparatus may further include a storage device for storing image information that is read by the light receiving device receiving light reflected by the irradiated object.

The display apparatus may have a function of displaying image information that is read by the light receiving device receiving light reflected by the irradiated object.

The display apparatus may also have a function of displaying the read image information in an inverted position.

An image reading/displaying system of the present invention includes: the display apparatus of the present invention; and a display medium to which the image information is written by the display apparatus displaying the read image information. Thus, the object set forth above is realized. Herein, the term “image reading/displaying system” refers to a system having at least one of a function of reading an image and a function of displaying an image.

The display medium may include a display medium layer, a pair of electrodes opposing each other via the display medium layer therebetween, and a photoconductive layer provided on a display medium layer side of one of the pair of electrodes.

A voltage may be applied to the pair of electrodes of the display medium by using a power supplied from the display apparatus.

Thus, the present invention provides a display apparatus capable of reading an image in addition to displaying an image, and an image reading/displaying system incorporating the same. In the display apparatus of the present invention, the display panel has both a function of displaying an image and a function of reading an image, and the light used for displaying an image and the light used for reading an image are commonly output from the same light emitting device. Therefore, it is possible to display and read image information with a simple, thin and light-weight structure.

### BRIEF DESCRIPTION OF THE DRAWINGS

FIG. 1 is a cross-sectional view schematically illustrating a portion of a display apparatus 100 according to one embodiment of the present invention corresponding to one pixel.

FIG. 2 is a plan view schematically illustrating a portion of the display apparatus 100 according to one embodiment of the present invention corresponding to one pixel.

FIG. 3 is an equivalent circuit diagram illustrating an example of a light emission control section used in the display apparatus 100.

FIG. 4 is an equivalent circuit diagram illustrating an example of a control circuit used in the display apparatus 100.

FIG. 5 is a cross-sectional view schematically illustrating a portion of a display apparatus 200 according to another embodiment of the present invention corresponding to one pixel.

FIG. 6 is a plan view schematically illustrating a portion of the display apparatus 200 according to another embodiment of the present invention corresponding to one pixel.

FIG. 7 is a flow chart illustrating the flow of an operation from the step of reading an image to the step of displaying the read image, in a case where the display apparatus of the present invention is capable of displaying image information obtained by reading an image.

FIG. 8 is a block diagram illustrating an example of a detection circuit used in the display apparatus 100.

FIG. 9 is a block diagram illustrating the relationship among various components in a case where an image is displayed based on a video signal produced by an arithmetic circuit in the display apparatus 100.

FIG. 10 is a cross-sectional view schematically illustrating an image reading/displaying system 1000 according to one embodiment of the present invention.

FIG. 11A and FIG. 11B are diagrams each illustrating the relationship between an image displayed by the display apparatus 200 and an image displayed by a display medium 800.

FIG. 12 is a cross-sectional view schematically illustrating another display medium 900 used in an image reading/displaying system according to one embodiment of the present invention.

FIG. 13 is a flow chart illustrating the flow of an operation from the step of reading an image to the step of saving the image, in a case where the display apparatus of the present invention is capable of saving, as electronic information, image information obtained by reading an image.

FIG. 14A, FIG. 14B and FIG. 14C are diagrams schematically illustrating an example of the shape of an opening in an electrode of a light emitting device, and an example of the relative arrangement of the opening and a light receiving device.

FIG. 15 is a cross-sectional view schematically illustrating a portion of a display apparatus 300 according to still another embodiment of the present invention corresponding to one pixel.

FIG. 16 is a cross-sectional view schematically illustrating a portion of a display apparatus 400 according to still another embodiment of the present invention corresponding to one pixel.

FIG. 17 is a cross-sectional view schematically illustrating a portion of a display apparatus 500A according to still another embodiment of the present invention corresponding to one pixel.

FIG. 18 is a cross-sectional view schematically illustrating a portion of a display apparatus 500B according to still another embodiment of the present invention corresponding to one pixel.

FIG. 19 is a cross-sectional view schematically illustrating a portion of a display apparatus 500C according to still another embodiment of the present invention corresponding to one pixel.

FIG. 20 is a cross-sectional view schematically illustrating a portion of a display apparatus 600A according to still another embodiment of the present invention corresponding to one pixel.

FIG. 21 is a cross-sectional view schematically illustrating a portion of a display apparatus 600B according to still another embodiment of the present invention corresponding to one pixel.

FIG. 22 is a cross-sectional view schematically illustrating a portion of a display apparatus 600C according to still another embodiment of the present invention corresponding to one pixel.

FIG. 23A and FIG. 23B are a plan view and a cross-sectional view, respectively, illustrating a preferred orientation of light emitting molecules in a light emitting layer.

FIG. 24 is a diagram schematically illustrating the anisotropy of light emission of a light emitting molecule.

FIG. 25A and FIG. 25B are a plan view and a cross-sectional view, respectively, illustrating an orientation of light emitting molecules in a light emitting layer.

FIG. 26A and FIG. 26B schematically illustrate the localization of a light emitting portion in a light emitting layer.

### BEST MODE FOR CARRYING OUT THE INVENTION

Display apparatuses according to embodiments of the present invention will now be described with reference to the drawings. Note that while the following embodiments are directed to active matrix type organic EL (electroluminescence) display apparatuses, the present invention is not limited to these embodiments.

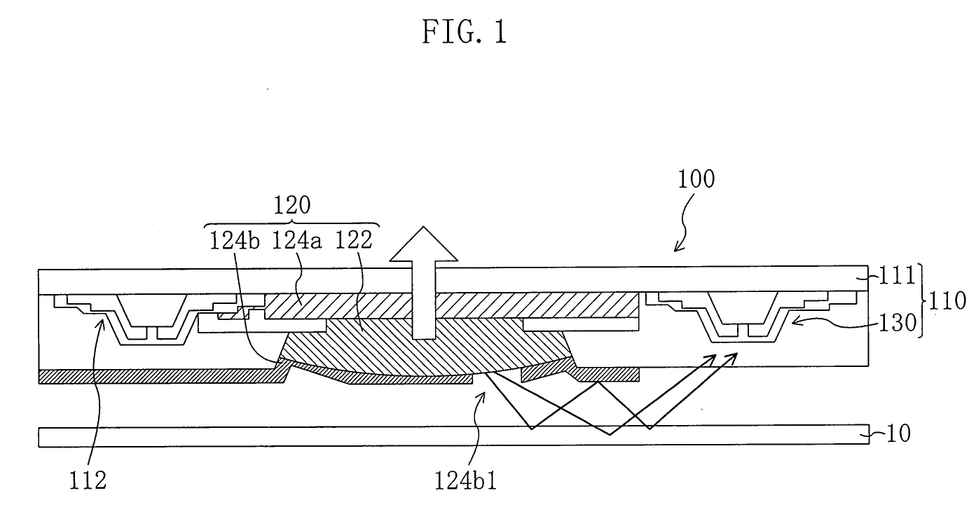

The structure of a display apparatus 100 according to one embodiment of the present invention will be described with reference to FIG. 1. The display apparatus 100 is an organic EL display apparatus including a plurality of pixels, and FIG. 1 is a cross-sectional view schematically illustrating a portion of the display apparatus 100 corresponding to one pixel. The plurality of pixels are typically arranged in a matrix pattern. Note that in the subsequent figures, components that are substantially the same in function as those of the display apparatus 100 will be denoted by the same reference numerals and will not be further described below.

The display apparatus 100 includes a display panel 110 including an organic EL device 120 as a light emitting device for each of a plurality of pixels, and a light receiving device 130 provided on the display panel 110 for each of the pixels. Note that the light emitting device is not limited to an organic EL device, but may alternatively be an inorganic EL device, or an electrochemical light emitting device.

The display panel 110 displays an image by using light that is output from the organic EL device 120 toward the panel front side (i.e., toward the viewer, or the upward direction in FIG. 1).

The light receiving device 130 receives a portion of light output from the organic EL device 120 toward the panel back side (i.e., away from the viewer, or the downward direction in FIG. 1) that is reflected by an irradiated object (e.g., a display medium such as a printed matter) 10 located on the panel back side.

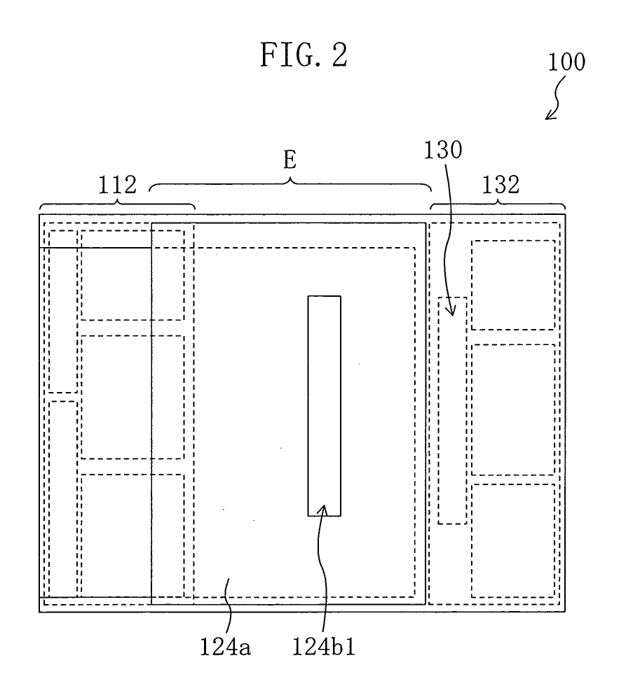

The structure of the display apparatus 100 will be described in greater detail with reference to FIG. 1 and FIG. 2. FIG. 2 is a plan view schematically illustrating a portion of the display apparatus 100 corresponding to one pixel.

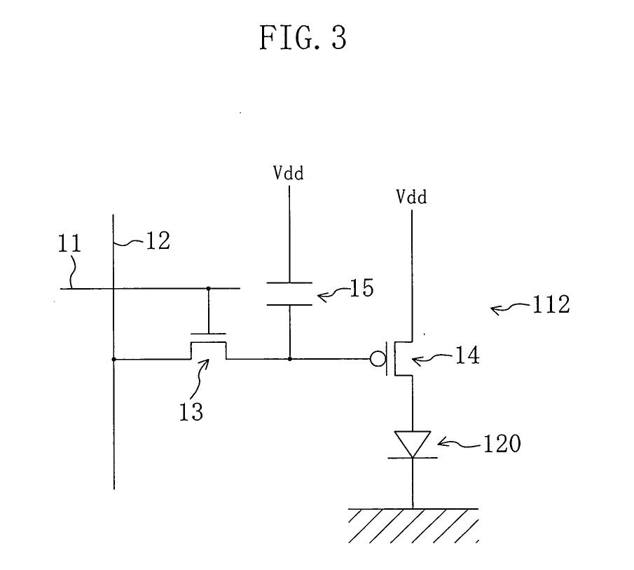

In the present embodiment, the display panel 110 of the display apparatus 100 is an active matrix type display panel including a substrate (e.g., a glass substrate) 111, and a light emission control section 112 provided on the substrate 111 for controlling the light emission of the organic EL device 120. In a case where an organic EL device is used as the light emitting device, the light emission control section 112 provided for each of the pixels typically includes a plurality of switching devices (e.g., TFTs) and a capacitor. For example, the light emission control section 112 may be a known light emission control section for an organic EL display apparatus as illustrated in FIG. 3. The light emission control section 112 illustrated in FIG. 3 includes a first TFT 13 connected to a scanning signal 11 and a signal line 12, a second TFT 14 connected to the power supply Vdd and the organic EL device 120, and a capacitor 15 connected to the first TFT 13 and the second TFT 14.

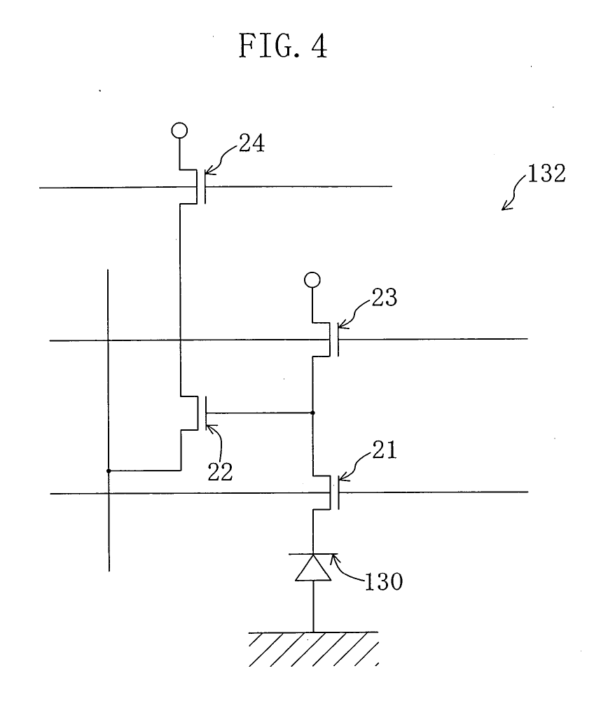

Moreover, as illustrated in FIG. 1 and FIG. 2, the organic EL device 120 and the light receiving device 130 are also provided on the substrate 111. In the illustrated example, the light emission control section 112, the organic EL device 120 and the light receiving device 130 as described above are provided on one surface of the substrate 111 on the back side (the side away from the viewer). Furthermore, in the illustrated example, a control circuit 132 connected to the light receiving device 130 is provided on the substrate 111 for each of the pixels. The control circuit 132 typically has a function of reading out a signal, a function of amplifying a read-out signal, and a function of resetting a device for amplifying a signal. For example, the control circuit 132 includes a read out transistor 21 for reading out a signal, an amplification transistor 22 for amplifying the read-out signal, a resetting transistor 23 for resetting the amplification transistor 22, an addressing transistor 24, etc., as illustrated in FIG. 4.

The organic EL device 120 includes a light emitting layer 122 and a pair of electrodes 124a and 124b interposing the light emitting layer 122 therebetween, as illustrated in FIG. 1. One of the pair of electrodes 124a and 124b that is provided closer to the viewer, i.e., the electrode 124a, is made of a transparent conductive material (e.g., ITO), is electrically connected to the light emission control section 112, and functions as an anode. Moreover, the electrode 124b provided on the back side is typically made of a metal (e.g., Ca and Ag), and functions as a cathode. The light emitting layer 122 emits light according to the level of the current supplied to the organic EL device 120 via the light emission control section 112.

The anode 124a, which is provided on the viewer side (the panel front side) of the light emitting layer 122, is made of a transparent conductive material. Therefore, light emitted from the light emitting layer 122 is output toward the viewer and thus used for displaying an image. The display apparatus 100 is a so-called “bottom emission type” organic EL display apparatus, in which light that is output toward and through the substrate 111 is used for displaying an image. Moreover, the cathode 124b provided on the back side of the light emitting layer 122 includes an opening 124b1, and a portion of light emitted from the light emitting layer 122 is output toward the back side via the opening 124b1 so as to irradiate the irradiated object 10.

The light receiving device 130 receives light reflected by the irradiated object 10 and detects the intensity thereof. The light receiving device 130 may be, for example, a photodiode.

The organic EL device 120 and the light emission control section 112 of the display apparatus 100 can be manufactured by using a known method for manufacturing an organic EL display apparatus. Moreover, the light receiving device 130 and the control circuit 132 connected to the light receiving device 130 can also be manufactured by using a known manufacturing method. In a structure using the display panel 110 of an active matrix type as in the present embodiment, the light receiving devices 130 and the control circuits 132 can be formed, on the substrate 111 on which the light emission control sections 112 of the display panel 110 are to be formed, by using a process similar to that for forming the light emission control sections 112. In this way, it is no longer necessary to later form the light receiving devices 130 and the control circuits 132 on the display panel 110 or to provide extra wiring for routing, whereby it is possible to reduce the power consumption while suppressing an increase in the cost. Moreover, in a case where the display panel 110 of an active matrix type is used, the monolithic substrate 111 with the light emission control sections 112, the light receiving devices 130, the control circuits 132, etc., formed therein can be suitably manufactured by using, as a semiconductor layer, a polysilicon layer or a continuous grain silicon (CGS) layer having a high electron mobility.

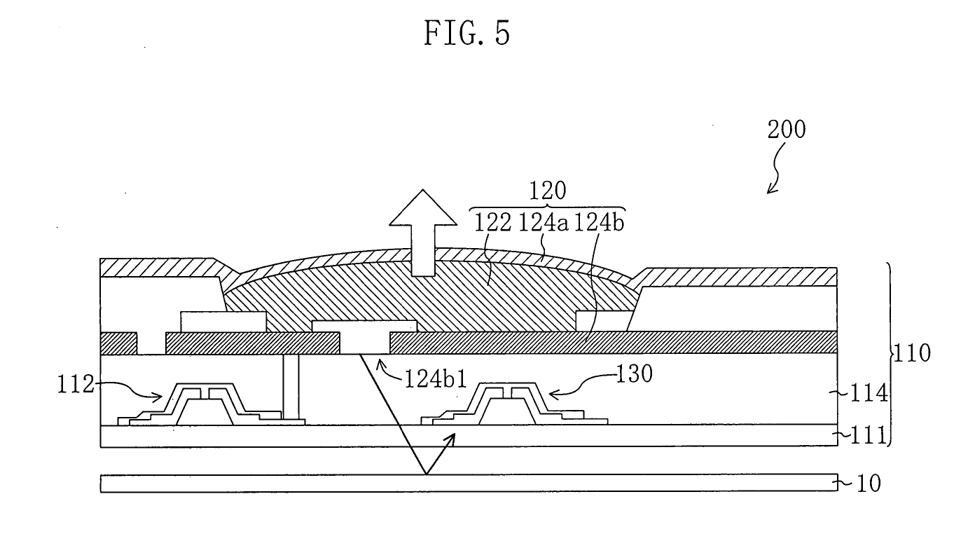

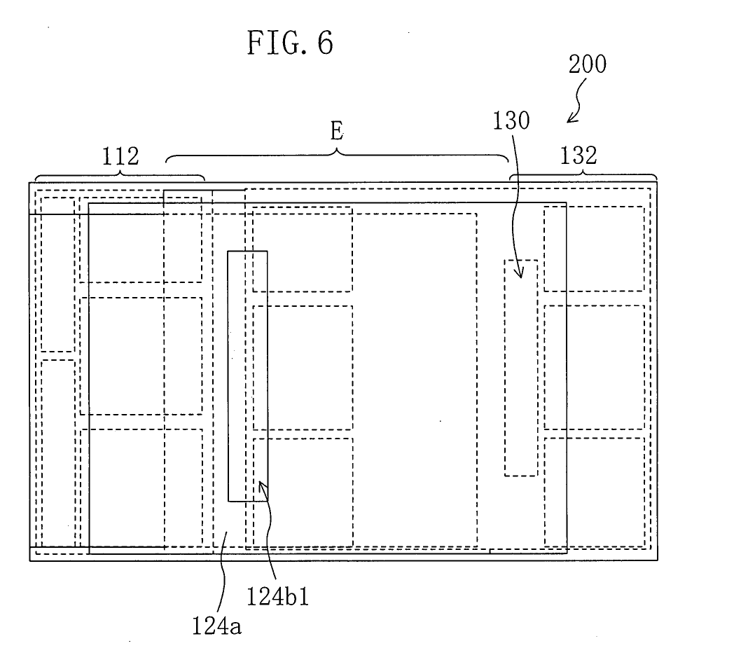

Note that while the description above is directed to the display apparatus 100 of a bottom emission type, the present invention can of course be used with a display apparatus of a so-called “top emission type”. FIG. 5 and FIG. 6 schematically illustrate a display apparatus 200 according to another embodiment of the present invention. FIG. 5 is a cross-sectional view schematically illustrating a portion of the display apparatus 200 corresponding to one pixel, and FIG. 6 is a plan view schematically illustrating a portion of the display apparatus 200 corresponding to one pixel.

The display apparatus 200 differs from the display apparatus 100 in that it is a so-called “top emission type” organic EL display apparatus, in which light that is output away from the substrate 111 is used for displaying an image.

In the display apparatus 200, the organic EL device 120 as a light emitting device, the light emission control section 112, the light receiving device 130 and the control circuit 132 are provided on the viewer side of the substrate 111.

More specifically, the light emission control section 112, the light receiving device 130 and the control circuit 132 are provided on one surface of the substrate 111 that is closer to the viewer, with a flattening layer 114 being formed so as to cover these components. The organic EL device 120 is provided on the flattening layer 114.

One of the pair of electrodes 124a and 124b interposing the light emitting layer 122 therebetween that is provided closer to the viewer, i.e., the electrode 124a, is made of a transparent conductive material (e.g., ITO), and functions as an anode. Moreover, the electrode 124b provided on the back side is typically made of a metal, is electrically connected to the light emission control section 112, and functions as a cathode.

The anode 124a, which is provided on the viewer side of the light emitting layer 122, is made of a transparent conductive material. Therefore, light emitted from the light emitting layer 122 is output toward the viewer and thus used for displaying an image. Moreover, the cathode 124b provided on the back side of the light emitting layer 122 includes the opening 124b1, and a portion of light emitted from the light emitting layer 122 is output toward the back side via the opening 124b1 so as to irradiate the irradiated object 10.

Since the display apparatus 200 is of a top emission type, it is possible to employ such a structure that the organic EL device 120 is overlaid on the light emission control section 112, or the like, whereby it is possible to increase the aperture ratio as compared to that of a bottom emission type display apparatus, and thus to realize a higher brightness and a higher definition.

Now, the operation of the display apparatuses 100 and 200 will be described. The display apparatuses 100 and 200 can not only display image information, but also read image information.

First, how image information is displayed will be described. An image is displayed by the organic EL device 120, provided for each pixel, emitting light at a predetermined intensity. When an image is displayed, a light emitting region E as shown in FIG. 2 and FIG. 6 contributes to the image display. In the present embodiment, the organic EL device 120 is driven in an active matrix driving mode by the light emission control section 112, which is also provided for each pixel.

Next, how image information is read will be described. As the organic EL device 120 emits light, the irradiated object 10 located on the panel back side is irradiated with the light. Light that is reflected by the irradiated object 10 is received by the light receiving device 130 provided for each pixel, and the intensity of the light is detected, thereby reading the image information of the surface of the irradiated object 10. If the apparatus is provided with light emitting devices that emit different colors of light (e.g., organic EL devices that emit red, green and blue light), color information of the surface of the irradiated object 10 can be read, whereby the image information can be read as color image information (information of a colored image).

The display apparatuses 100 and 200 may be capable of displaying the read image information, or saving the read image information as electronic information, or may be capable of both displaying and saving the read image information.

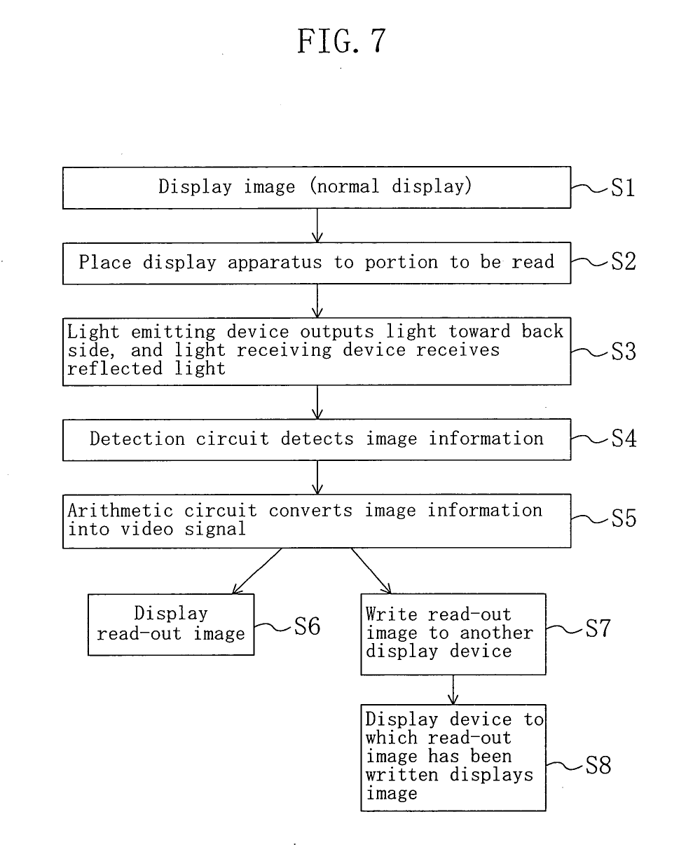

FIG. 7 illustrates an example of the flow of an operation from the step of reading an image to the step of displaying the image, in a case where the display apparatus is capable of displaying the read image information.

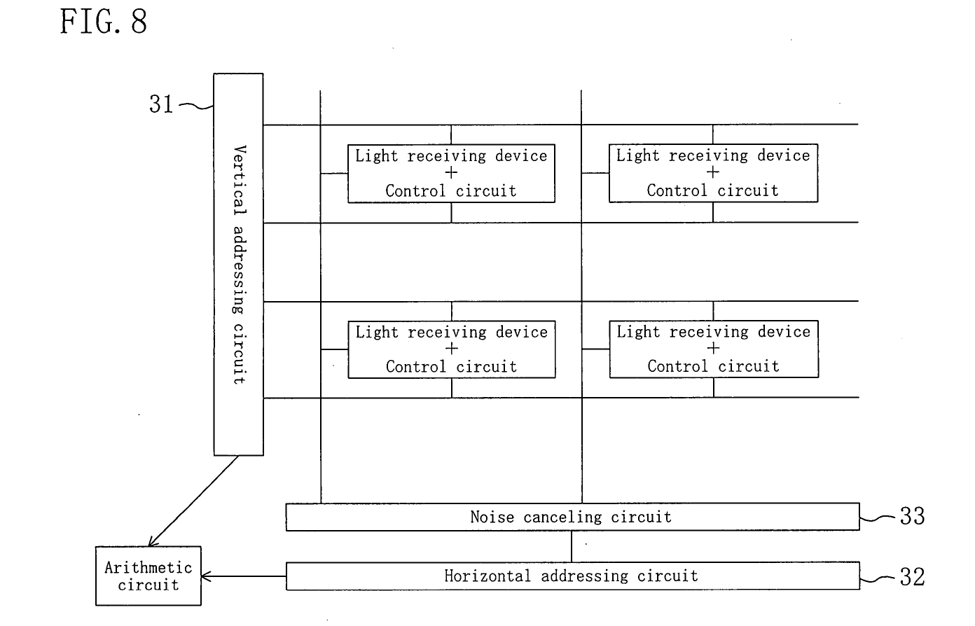

First, the display apparatus displaying an image (normal display state: S1) is placed over a portion of the irradiated object 10 to be read by the apparatus (S2). Then, the light emitting devices emit light toward the back side, and light reflected by the irradiated object 10 is received by the light receiving device 130, provided for each pixel, and the intensity of the received light is detected as a signal (S3). Then, the signal detected by the light receiving device 130 is read out by the control circuit 132 connected to the light receiving device 130, and the read-out signal is detected by a detection circuit as image information (S4). For example, the detection circuit includes a vertical addressing circuit 31 and a horizontal addressing circuit 32 for addressing and detecting the information read by the control circuit 132, a noise canceling circuit 33 for canceling noise, etc., as illustrated in FIG. 8.

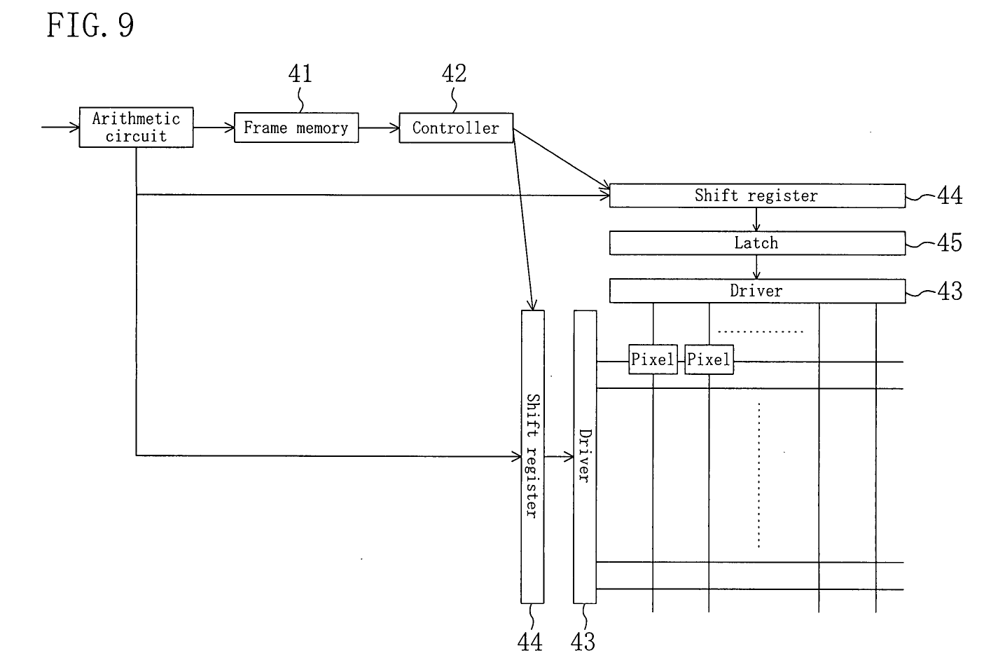

Then, the detected image information is corrected or modified by an arithmetic circuit, which is provided outside the display area, so as to be converted into a video signal (S5). Then, the light emission control section 112 controls the light emitting device to emit light at a predetermined intensity based on the video signal produced by the arithmetic circuit, so as to display an image (S6). At this time, the light emission control section 112 may control the light emitting device to emit light at a predetermined intensity so as to write the image information on a writable display medium, which is separately provided (S7), so that the image information is displayed by the display medium (S8). Note that when the light emission control section 112 controls the light emitting device to emit light based on a video signal, the video signal may be input directly to a driver 43 (strictly speaking, via a shift register 44 and a latch 45), or may be input to the driver after once writing it to a frame memory 41, i.e., via the frame memory 41 and a controller 42, as illustrated in FIG. 9.

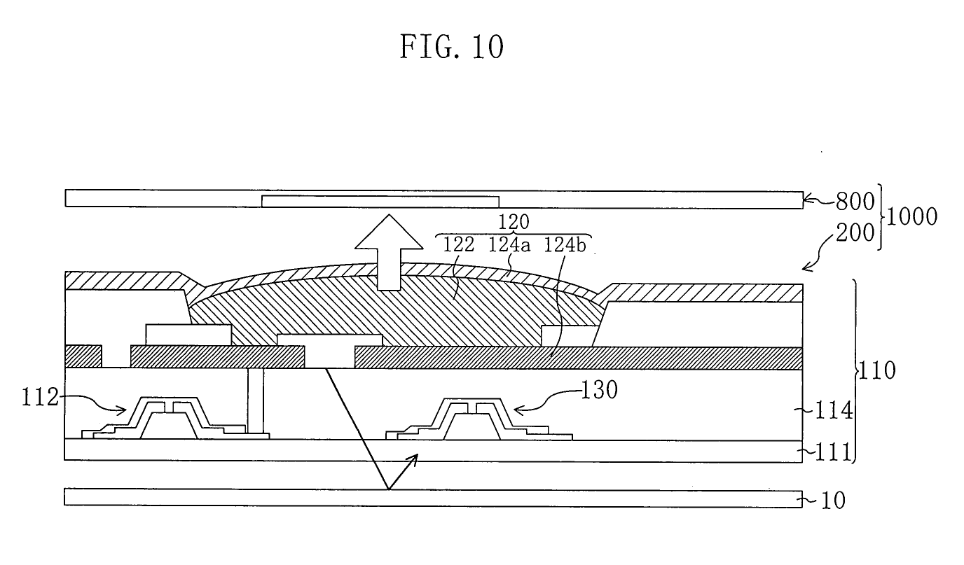

FIG. 10 illustrates a display medium 800 to which image information can be written. The display medium 800 is a paper-like display medium such as an optically writable display element or recycled paper made of a material whose color can be changed by light.

As the light emitting device emits light at a predetermined intensity based on the read image information, the image information is written to the display medium 800, whereby the image can be displayed by the display medium 800. Thus, the display medium 800 and the display apparatus 200 illustrated in FIG. 10 together function as an image reading/displaying system 1000. With the image reading/displaying system 1000, an image of interest can be copied (read) by the display apparatus 200, and the image can be pasted (written) to the display medium 800. Therefore, the display apparatus 100 or 200 as described above may be called a “copy-and-paste display”, and the image reading/displaying system 1000 may be called “copy-and-paste system”.

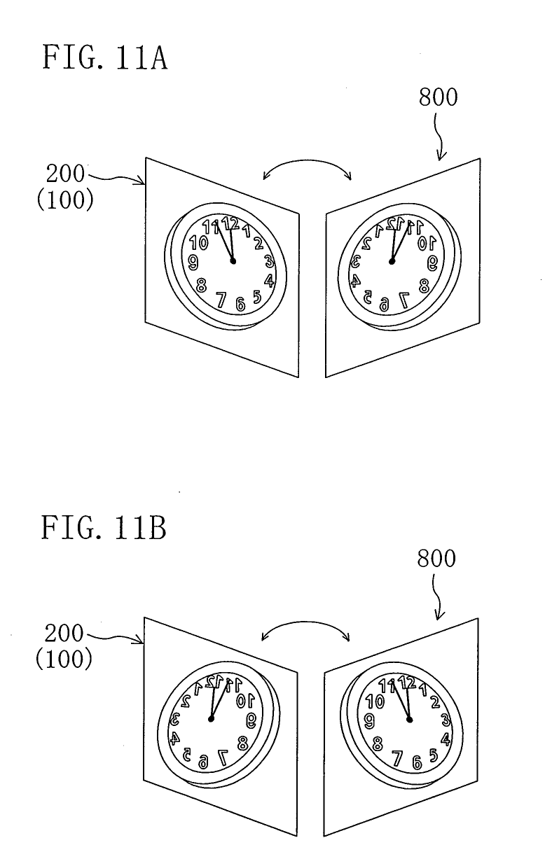

Note that when an optical writing operation is performed with the display medium 800 opposing the display apparatus 200, as illustrated in FIG. 10, the image displayed by the display apparatus 200 (i.e., the read image) is displayed on the display medium 800 in an inverted position, as illustrated in FIG. 11A. If the display apparatus 200 is capable of displaying a read image in an inverted position, the read image can be displayed in a normal, original position on the display medium 800 by writing (displaying) an inverted version of the read image to the display medium 800, as illustrated in FIG. 11B.

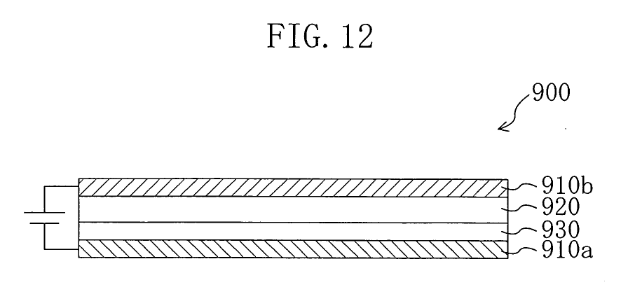

FIG. 12 illustrates another display medium 900 to which image information can be written. The display medium 900 is an electrically writable display element including a photoconductive layer (photoelectric conversion layer) 930.

The display medium 900 includes a display medium layer 920, and a pair of electrodes 910a and 910b opposing each other via the display medium layer 920 therebetween. The photoconductive layer (e.g., a photoconductive film) 930 is provided on one surface of the electrode 910a that is closer to the display medium layer 920.

For example, the display medium layer 920 may be a liquid crystal layer in which the orientation of the liquid crystal molecules is changed by an applied voltage, an electrochromic layer made of an inorganic or organic insulator whose color is changed by a positive or negative charge injected into the layer, or an electrophoretic display medium layer.

When the display medium 900 is placed over the display apparatus 100 (or the display apparatus 200), and the light emitting device is controlled to emit light based on the read image information, a conductivity distribution is created across the photoconductive layer 930 according to the distribution of the intensity of emitted light, whereby a voltage is applied to or a charge is injected into the display medium layer 920 according to the voltage applied between the electrodes 910a and 910b and the conductivity of the photoconductive layer 930, thus writing the image information.

It is preferred that the display medium layer 920 has a memory property. If the display medium layer 920 has a memory property, only by applying a voltage in a writing operation, an image can be displayed without having to continue to apply the voltage thereafter. The power for the writing operation can be supplied by the display apparatus 100 (or the display apparatus 200), in which case the power supply of the display medium 900 can be omitted.

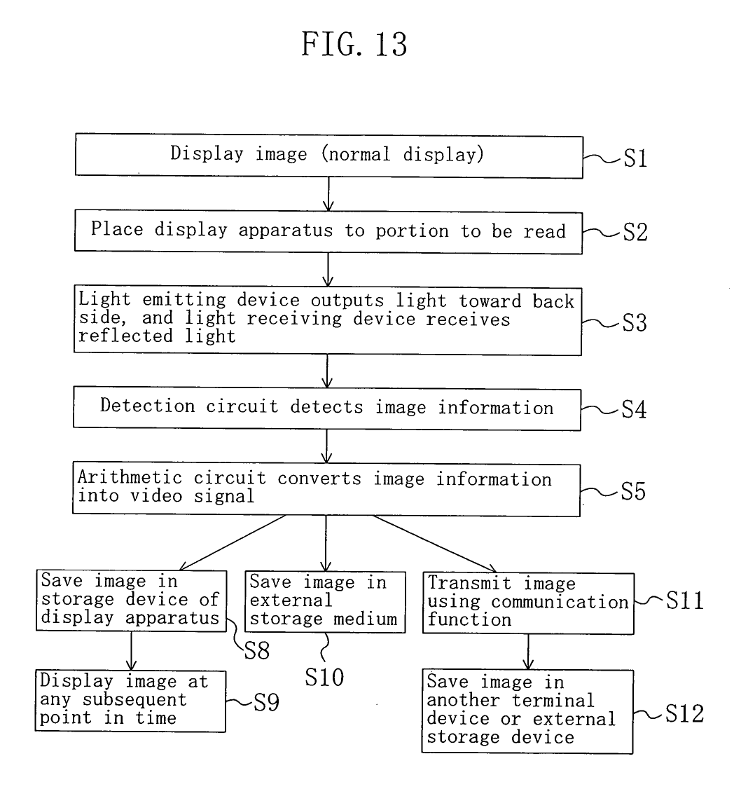

FIG. 13 illustrates an example of the flow of an operation from the step of reading an image to the step of saving the image, in a case where the display apparatus is capable of saving, as electronic information, image information obtained by reading an image.

First, an image is read as in the operation illustrated in FIG. 7 (S1 to S4). Then, a video signal produced by an arithmetic circuit (S5) is saved by storing it in a storage device (memory; not shown) provided in the display panel 110 (S8), and the light emitting device is controlled to emit light based on the video signal so as to display the image at any subsequent point in time (S9). Moreover, the produced video signal may be saved by recording it in an external recording medium (e.g., a memory card inserted into the display panel) (S10). Alternatively, the produced video signal may be transmitted to another terminal device or an external storage device by using a communication function (S11) and saved therein (S12).

The display apparatuses 100 and 200 display and read image information as described above.

As described above, the display apparatuses 100 and 200 each include light emitting devices (the organic EL devices 120) for outputting light to be used for displaying an image toward the panel front side (toward the viewer) and for outputting light toward the irradiated object on the panel back side (on the side away from the viewer), and the light receiving devices 130 for receiving light reflected by the irradiated object. Therefore, the display apparatuses 100 and 200 are capable of not only displaying an image but also reading image information of the surface of the irradiated object. Thus, the display apparatuses 100 and 200 function both as a flat display apparatus and as a flat scanner.

In the display apparatuses 100 and 200, the display panel 110 has both a function of displaying an image and a function of reading an image, and the light used for displaying an image and the light used for reading an image are commonly output from the same light emitting device. Therefore, it is possible to display and read image information with a simple, thin and light-weight structure.

Moreover, when a flexible display panel including a flexible substrate is used as the display panel 110, image information of a curved surface can be read by using the display panel while bending it along the curved surface.

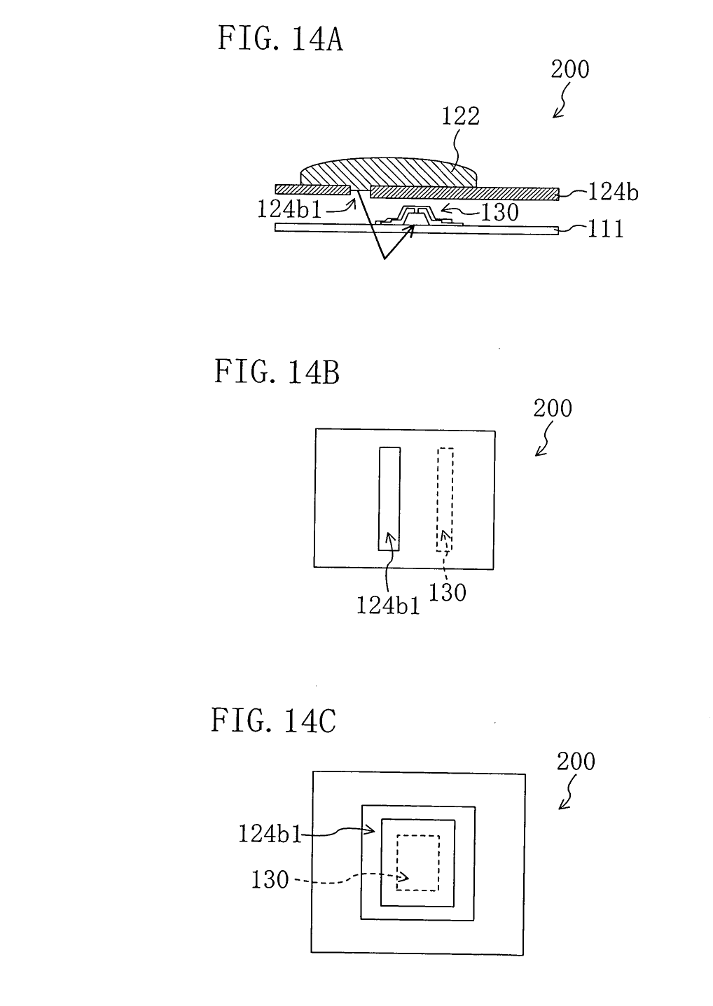

Note that while the description above is directed to a structure in which the opening 124b1 of the cathode 124b provided on the panel back side has a generally rectangular shape, as illustrated in FIG. 14A and FIG. 14B, with the light receiving device 130 being placed generally parallel to the long side of the opening 124b1, the present invention is not limited thereto. The shape of the opening 124b1 and the relative arrangement of the opening 124b1 and the light receiving device 130 are preferably determined so that light that is output from the organic EL device 120 via the opening 124b1 and reflected by the irradiated object is efficiently incident on the light receiving device 130. For example, if the opening 124b1 is formed so as to surround the light receiving device 130, as illustrated in FIG. 14C, it is possible to more efficiently receive light and to reduce the influence of ambient light or stray light coming from the environment.

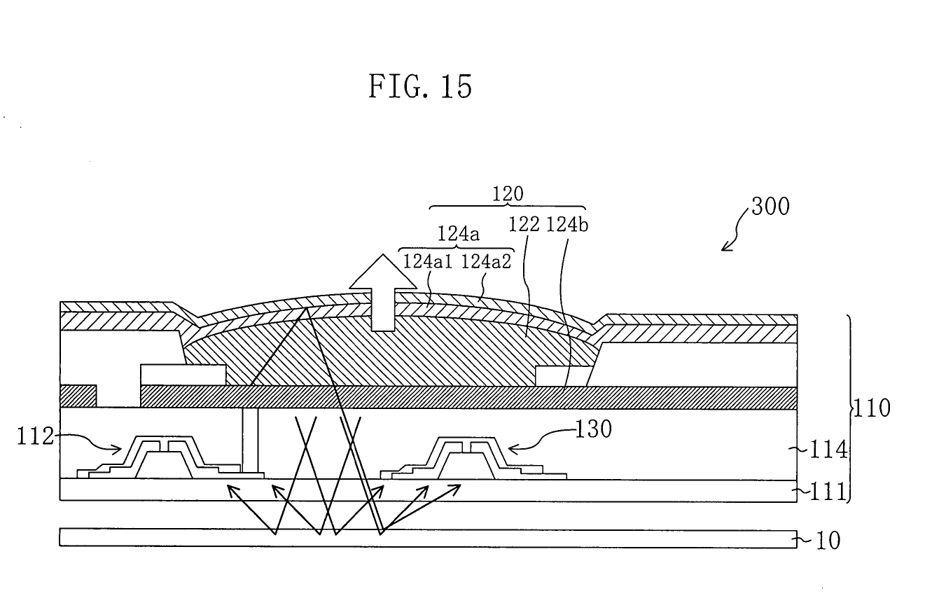

FIG. 15 illustrates a display apparatus 300 according to another embodiment of the present invention. The display apparatus 300 differs from the display apparatus 200 in that the anode 124a provided on the viewer side is a layered electrode made of a semi-transparent thin metal film (e.g., an Ag film having a thickness of 3 nm) 124a1 and a transparent conductive film (e.g., ITO) 124a2, and that the cathode 124b provided on the back side is made of a transparent conductive material (e.g., ITO).

In the display apparatus 300, the anode 124a provided on the viewer side of the light emitting layer 122 is formed by layering the semi-transparent thin metal film 124a1 and the transparent conductive film 124a2, whereby light emitted from the light emitting layer 122 is output toward the viewer and used for displaying an image. Note that the transparent conductive film 124a2 is provided on the thin metal film 124a1 for increasing the conductivity. Moreover, the cathode 124b provided on the back side of the light emitting layer 122 is made of a transparent conductive material, whereby light can be output toward the back side without having to provide an opening in the cathode 124b.

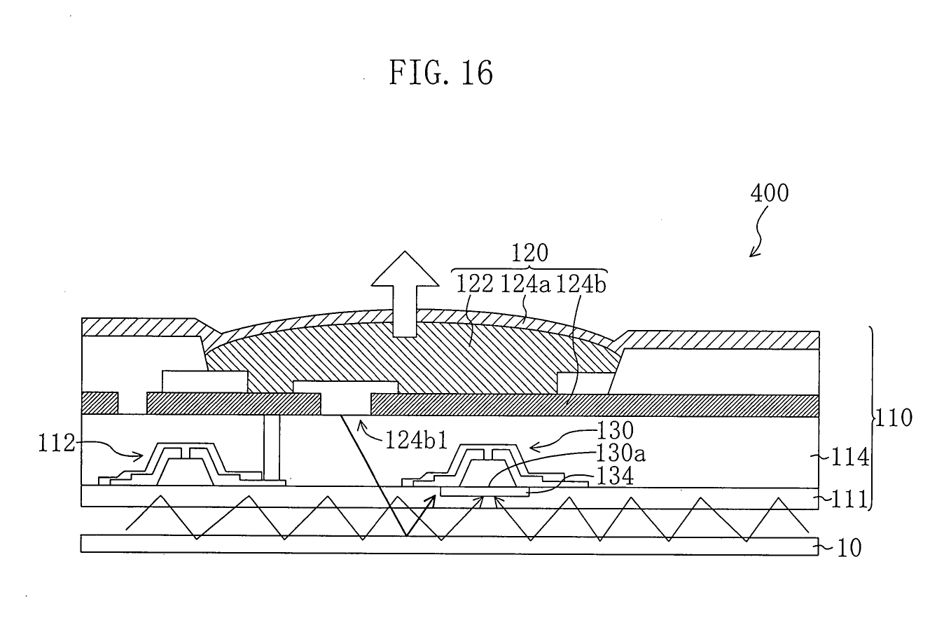

FIG. 16 illustrates a display apparatus 400 according to still another embodiment of the present invention. The display apparatus 400 differs from the display apparatus 200 in that the display panel 110 includes a color filter 134 that overlaps with at least a portion of a light receiving surface (the surface that is irradiated with light reflected by the irradiated object) 130a of the light receiving device 130.

The color filter 134 selectively absorbs, reflects or transmits light incident thereon according to the wavelength of the incident light. In the illustrated example, the color filter 134 selectively transmits therethrough light of a color that is emitted from the organic EL device 120 of the corresponding pixel, while absorbing or reflecting light of any other color. With such a color filter, it is possible to reduce the influence of stray light coming from the environment and thus to read image information with a high precision.

Note that while FIG. 16 illustrates a structure where the color filter 134 is provided immediately under the light receiving surface 130a of the light receiving device 130, the structure is not limited to this as long as the color filter 134 overlaps with at least a portion of the light receiving surface 130a. For example, the color filter 134 may be provided on the lower surface (the surface on the panel back side) of the substrate 111. Moreover, the color filter 134 may be provided for every light receiving device 130 of the display panel 110, or may alternatively be provided only for some of the light receiving devices 130.

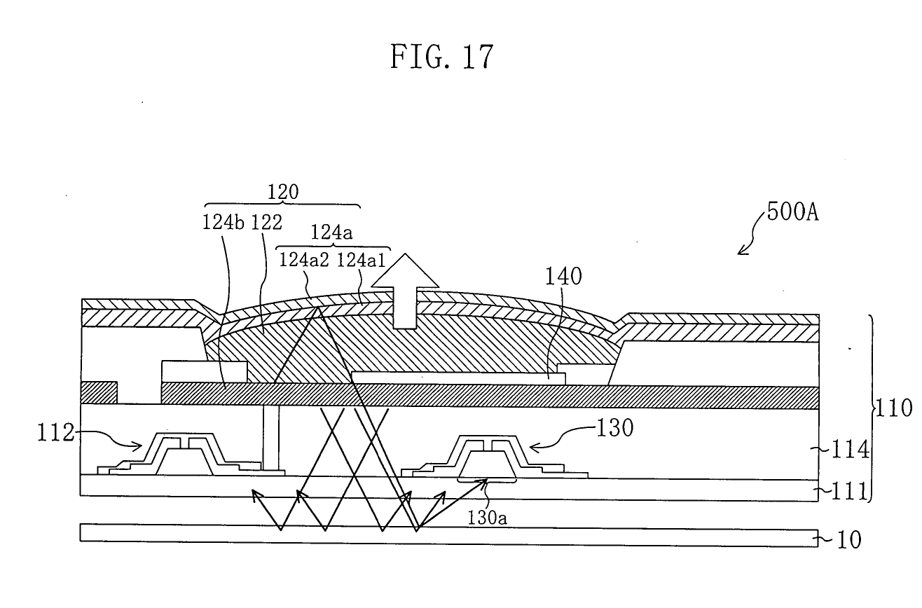

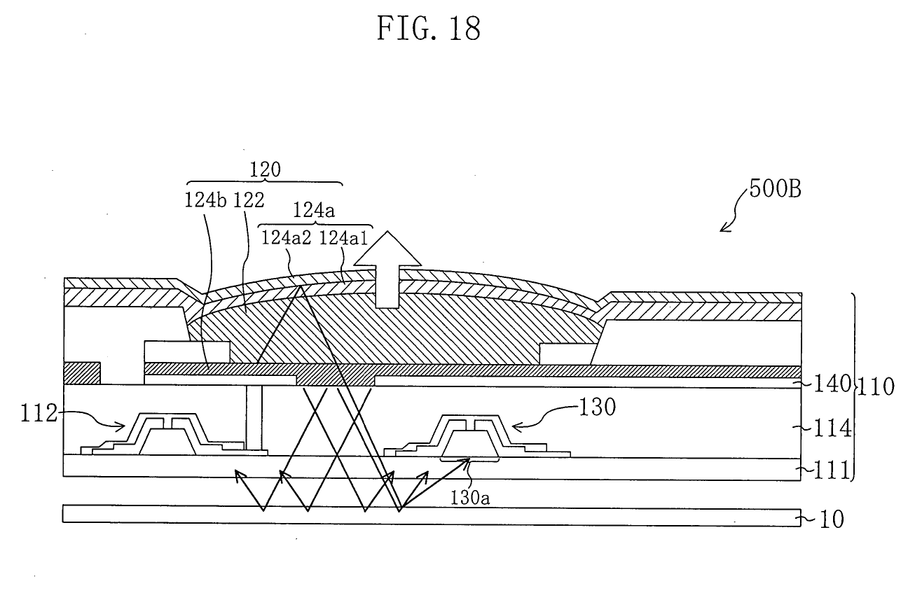

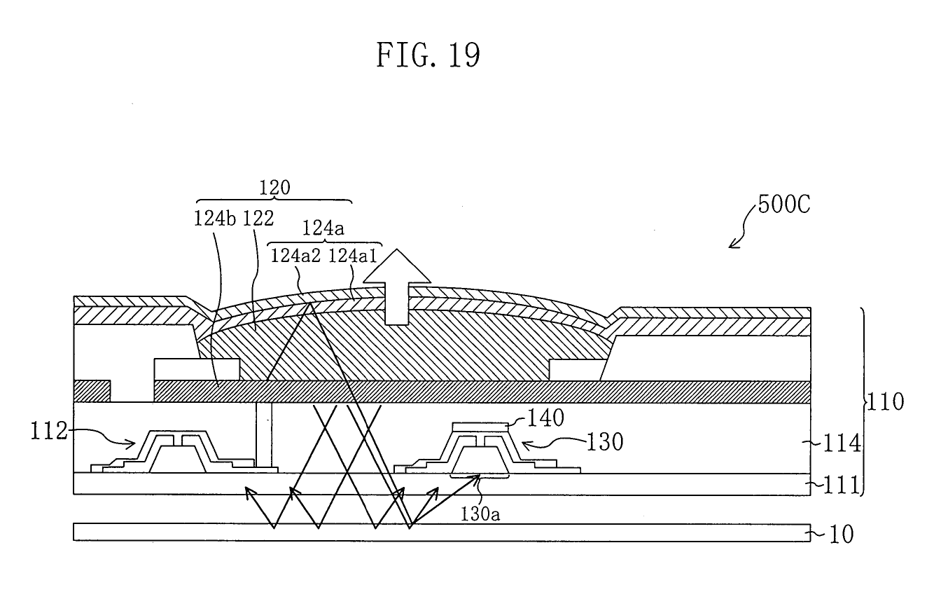

FIG. 17, FIG. 18 and FIG. 19 illustrate display apparatuses 500A, 500B and 500C, respectively, according to still another embodiment of the present invention. The display apparatuses 500A, 500B and 500C each differ from the display apparatus 300 in that the display panel 110 includes a light blocking layer 140 between the organic EL device 120 and the light receiving device 130.

The light receiving device 130 receives, at the light receiving surface 130a, light reflected by the irradiated object on the panel back side so as to detect the intensity of the light. In this process, if light from a light emitting device is directly incident on the light receiving device 130, the light receiving device 130 may operate erroneously. This is because the light receiving device 130 in some cases includes a member having semiconductor characteristics (e.g., a semiconductor film).

In the display apparatuses 500A, 500B and 500C, the light blocking layer 140 is provided between the light emitting device (the organic EL device 120) and the light receiving device 130, thereby preventing the light receiving device 130 from being directly irradiated with light from the light emitting device and thus preventing the light receiving device 130 from operating erroneously. Thus, it is possible to improve the reliability of the display apparatus (the reliability in reading image information).

The light blocking layer 140 may be provided on the upper surface of the cathode 124b, as illustrated in FIG. 17, or on the lower surface of the cathode 124b, as illustrated in FIG. 18. The light blocking layer 140 may be a light absorbing film or a light reflecting film (e.g., a metal film). When the light blocking layer 140 is a light reflecting film, a portion of light emitted from the light emitting layer 122 is reflected by the light blocking layer 140 toward the panel front side, thereby improving the display brightness. Moreover, the light blocking layer 140 may be formed directly on the light receiving device 130, as illustrated in FIG. 19.

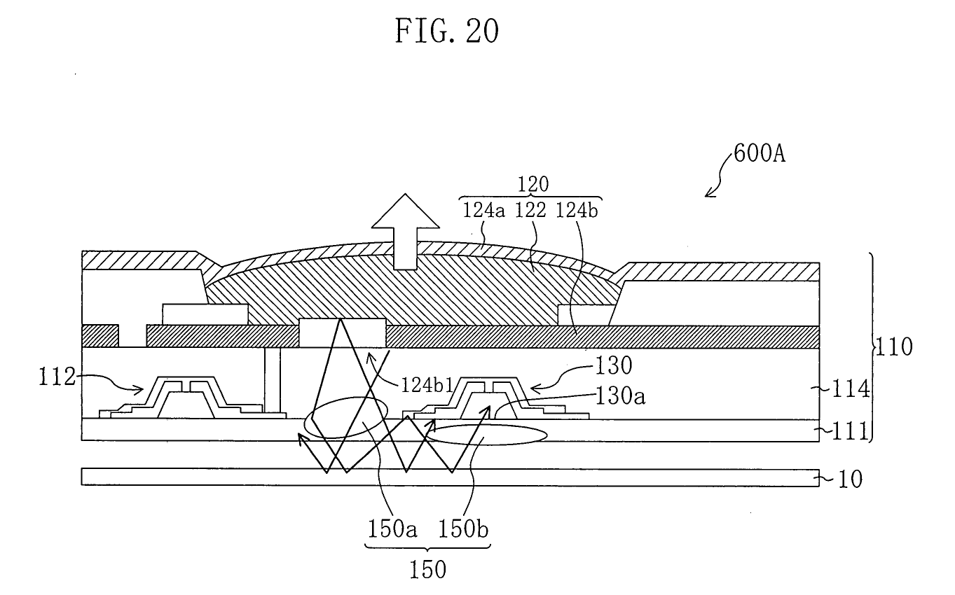

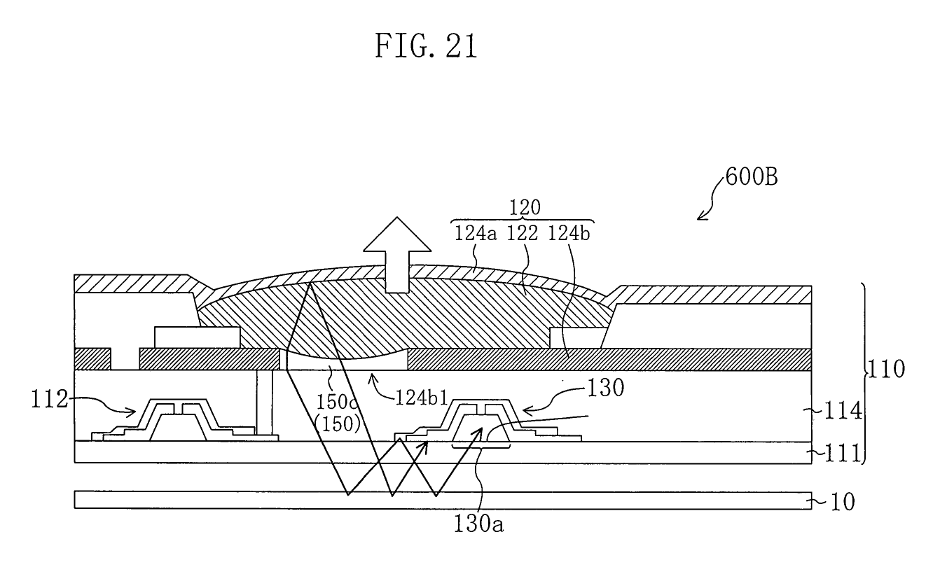

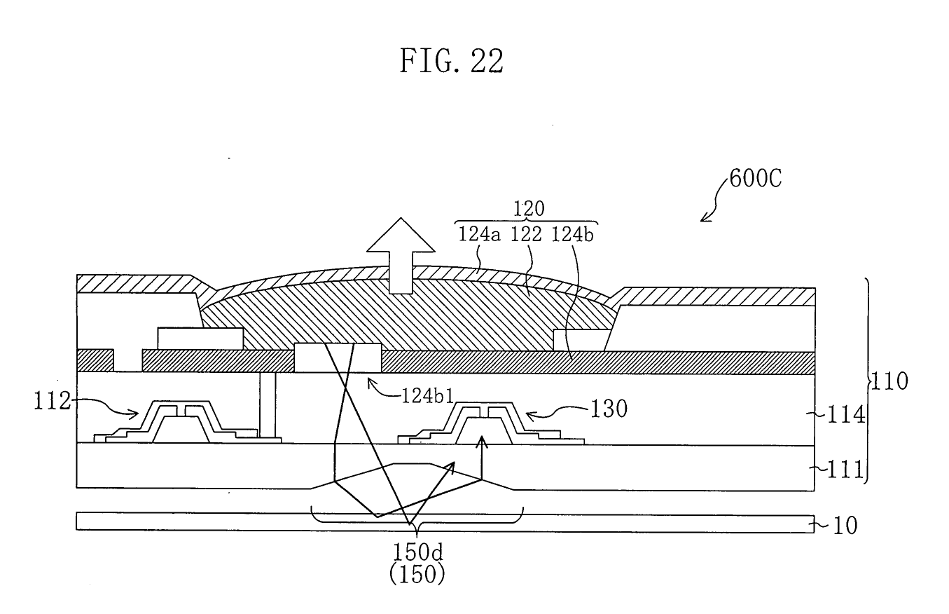

FIG. 20, FIG. 21 and FIG. 22 illustrate display apparatuses 600A, 600B and 600C, respectively, according to still another embodiment of the present invention. The display apparatuses 600A, 600B and 600C differ from the display apparatus 200 in that the display panel 110 includes a light converging section 150 provided on the panel back side of the organic EL device 120.

In the display apparatuses 600A, 600B and 600C, the light converging section 150 is provided on the panel back side of the light emitting device (the organic EL device 120), whereby light output from the light emitting device toward the panel back side and/or light reflected by the irradiated object to be incident on the light receiving device 130 is converged. Thus, light emitted from the light emitting device can be efficiently incident on the light receiving device 130.

For example, the light converging section 150 includes microlenses 150a and 150b that are formed in the substrate 111 on which the light emission control section 112 and the light receiving device 130 are to be formed, as illustrated in FIG. 20. The microlens 150a opposing the opening 124b1 of the cathode 124b functions to converge light that is emitted from the light emitting layer 122, and the microlens 150b opposing the light receiving surface 130a of the light receiving device 130 functions to converge light that is reflected by the irradiated object so as to be incident on the light receiving device 130. The microlenses 150a and 150b can be formed in the substrate 111 during the production of the substrate 111. The shape and arrangement of the microlenses 150a and 150b may be determined appropriately according to the material, the refractive index, the thickness, etc., of each component of the display panel 110. Note that one of the microlenses 150a and 150b may be omitted.

Alternatively, the light converging section 150 may be a meniscus-shaped transparent film (hereinafter referred to as “meniscus film”) 150c provided in the opening 124b1 in the cathode 124b and having a function as a lens, as illustrated in FIG. 21. The meniscus film 150c provided in the opening 124b1 in the cathode 124b converges light that is emitted from the light emitting layer 122.

The meniscus film 150c can be formed by dripping a small amount of a solution in which the material of the meniscus film 150c is dissolved into the opening 124b1 in the cathode 124b and then letting the solvent to evaporate. The shape of the meniscus film 150c is determined by the wettability (wettability for the solution to be dripped) of the conductive film (the cathode 124b) surrounding the opening 124b1 and that of the member under the cathode 124b (the flattening layer 114 in the illustrated example). The meniscus film 150c suitable for converging light can be formed by appropriately adjusting the wettability and the material, the refractive index, etc., of each component.

Alternatively, the light converging section 150 may be a sloped section 150d formed in the substrate 111, as illustrated in FIG. 22. In the illustrated example, the sloped section 150d is a depression formed on the lower surface (the surface on the panel back side) of the substrate 111. The depression has a protruding surface with respect to the straight line between the opening 124b1 and the light receiving device 130, whereby light emitted from the light emitting layer 122 and light reflected by the irradiated object 10 so as to be incident on the light receiving device 130 can be redirected so that the light is efficiently guided to the light receiving device 130.

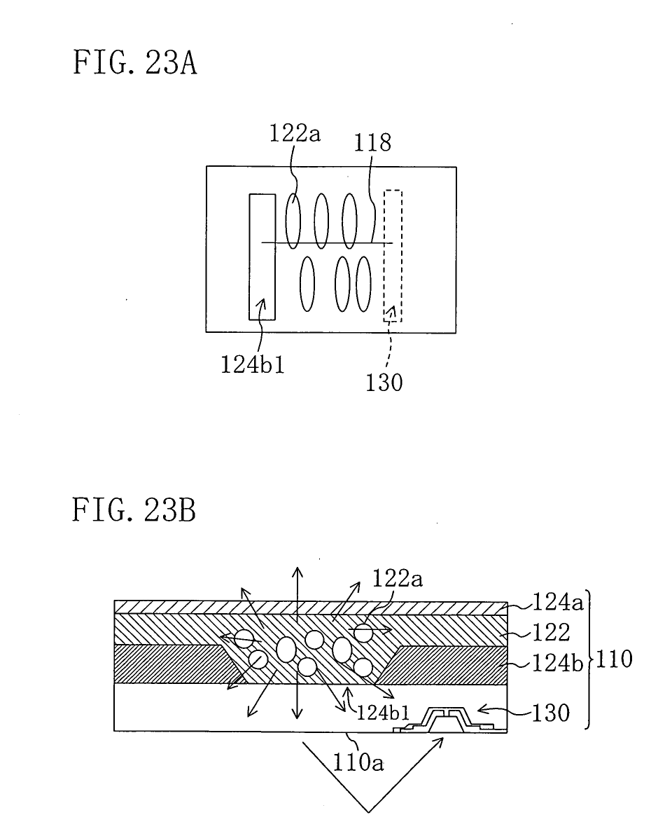

In the present embodiment, the organic EL device 120 is used as the light emitting device. The organic EL device 120 includes the light emitting layer 122, which contains light emitting molecules. As illustrated in FIG. 23A and FIG. 23B, in a case where the light emitting device includes a layer that contains light emitting molecules 122a, if the light emitting molecules 122a are oriented so as to be generally parallel to one surface 110a of the display panel 110 on the panel back side and generally perpendicular to a straight line (virtual line) 118 between the opening 124b1 and the light receiving device 130, light that is emitted from the light emitting layer 122 containing the light emitting molecules 122a can be efficiently incident on the light receiving device 130, for the following reason.

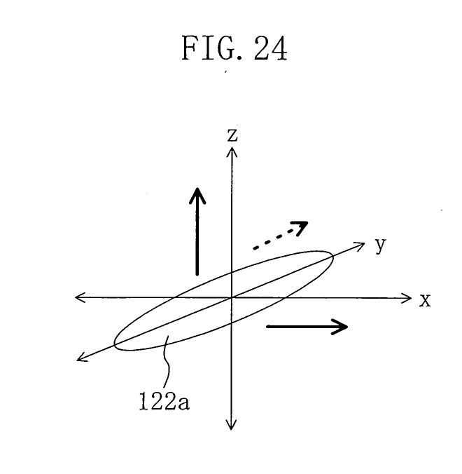

It is believed that the light emitting molecule (organic light emitting molecule) 122a contained in an organic EL device, or the like, has anisotropy in its emission brightness, as illustrated in FIG. 24 (Appl. Phys. Lett. 71 (18), 3 Nov. 1997, etc.). Specifically, while the light emitting molecule 122a emits light in its short axis directions (the x axis direction and the z axis direction in FIG. 24), it emits substantially no light in its long axis direction (the y axis direction in FIG. 24).

Therefore, if the light emitting molecules 122a are oriented in a certain direction, as compared with a case where they are in a random orientation, the light emission can be made directional, and the light can be incident on the light receiving device 130 more efficiently. Specifically, it is preferred that the light emitting molecules 122a are oriented in a direction such that light that spreads in the short axis direction of the light emitting molecules 122a can be efficiently output through the opening 124b1 onto the light receiving device 130. More specifically, it is preferred that the light emitting molecules 122a are oriented so as to be generally parallel to the surface 110a of the display panel 110 on the panel back side and generally perpendicular to the straight line (virtual line) 118 between the opening 124b1 and the light receiving device 130, as illustrated in FIG. 23A and FIG. 23B, whereby light emitted from the light emitting layer 122 containing the light emitting molecules 122a can be efficiently incident on the light receiving device 130.

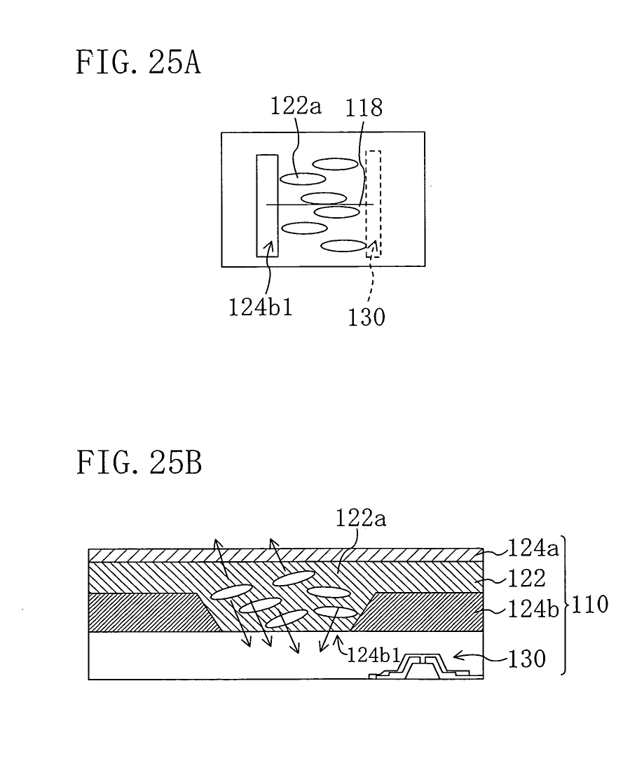

In contrast, if the light emitting molecules 122a are oriented so as to be generally parallel to the straight line (virtual line) 118 between the opening 124b1 and the light receiving device 130, for example, as illustrated in FIG. 25A and FIG. 25B, light emitted from the light emitting layer 122 containing the light emitting molecules 122a may not efficiently be output onto the light receiving device 130.

The light emitting molecules 122a can be oriented by any of various methods, including a method of providing an orientation regulating film under the light emitting layer 122, a rubbing method, an electric field treatment method, and an inclined vapor deposition method, selected depending on the material of the light emitting layer 122.

Moreover, by controlling the light emitting portion in the light emitting layer 122, light can be effectively emitted toward the back side of the light emitting layer 122. In an organic EL device, a charge is injected into a light emitting layer interposed by an anode, a cathode and a charge transport film, and excitation/light emission occurs through charge recombination in the light emitting layer. Since the light emitting layer itself has a charge transporting capability, the light emitting layer emits light while transporting a charge. However, the light emitting layer is liable to more transport a charge of one of hole and electron than the other, and light is emitted from a particular portion of the light emitting layer, not from the entire layer. The center of light emission is often shifted toward the anode side when the light emitting layer has an electron transporting capability, whereas it is often shifted toward the cathode side when the light emitting layer has a hole transporting capability. Therefore, by controlling the localization of the light emitting portion in the light emitting layer, light can be efficiently emitted through the back surface. Specifically, in a case where an opening is provided in the back side electrode through which emitted light is output, it is preferred that the light emitting portion of the light emitting layer is localized toward the electrode that includes the opening therein.

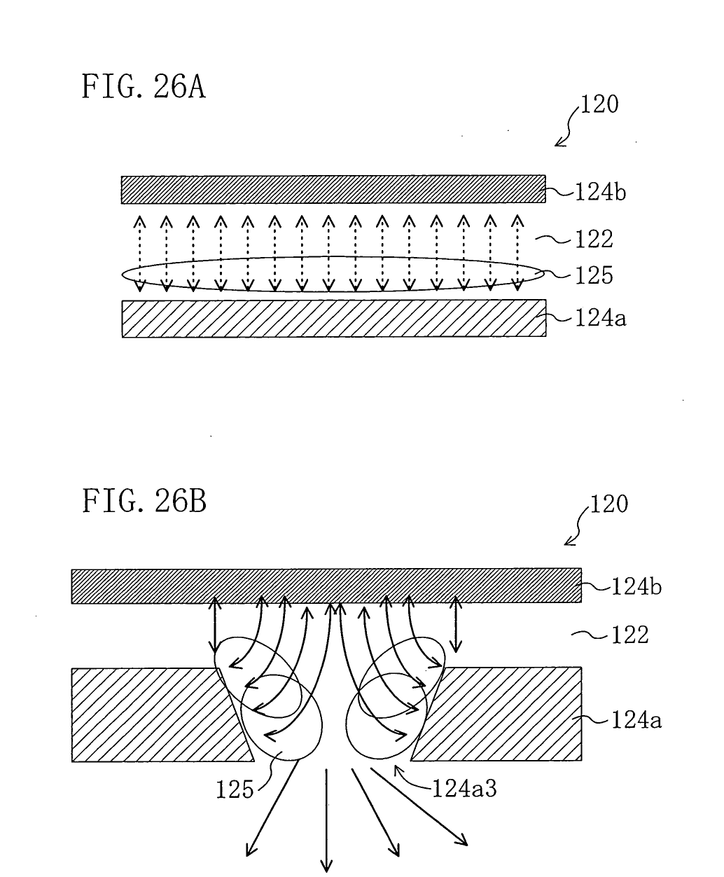

When the light emitting layer 122 having an electron transporting capability (having a high electron transporting capability) is used in the organic EL device 120 including the anode 124a on the back side and the cathode 124b on the front side, as illustrated in FIG. 26A, light emission occurs only in the vicinity of the anode 124a. Countless equipotential lines are defined perpendicular to the lines of electric force represented by arrows in FIG. 26A, and a light emitting portion 125 extends along the equipotential lines. Therefore, as illustrated in FIG. 26B, by appropriately determining the area and shape of an opening 124a3 in the anode 124a and the level of the electron transporting capability of the light emitting layer 122 so that light emission occurs only through the opening 124a3 in the anode 124a, light can be efficiently output through the opening 124a3 so as to efficiently irradiate the irradiated object with the output light.

Note that when displaying an image in a gray scale while reading the image simultaneously, the read signal can be corrected by using known gray scale signals so as to obtain an appropriate read image signal.

### INDUSTRIAL APPLICABILITY

As described above, the display apparatus of the present invention and the image reading/displaying system incorporating the same are useful for a display apparatus capable of reading an image in addition to displaying an image, and an image reading/displaying system incorporating the same, and are particularly suitable for displaying and reading image information with a simple, thin and light-weight structure.

While the present invention has been described in preferred embodiments, it will be apparent to those skilled in the art that the disclosed invention may be modified in numerous ways and may assume many embodiments other than those specifically set out and described above. Accordingly, it is intended by the appended claims to cover all modifications of the invention that fall within the true spirit and scope of the invention.

1. A display apparatus, comprising:
a display panel including a light emitting device for each of a plurality of pixels for displaying an image by using light that is output from the light emitting device toward a panel front side; and
a light receiving device provided on the display panel for each of the plurality of pixels for receiving a portion of light output from the light emitting device toward a panel back side that is reflected by an irradiated object located on the panel back side.

2. The display apparatus of claim 1, wherein the display panel is an active matrix type display panel including a substrate and a light emission control section provided on the substrate for controlling light emission of the light emitting device, with the light emitting device and the light receiving device being provided on the substrate.

3. The display apparatus of claim 1, wherein the display panel includes a color filter provided so as to overlap with at least a portion of a light receiving surface of the light receiving device.

4. The display apparatus of claim 1, wherein the display panel includes a light blocking layer provided between the light emitting device and the light receiving device.

5. The display apparatus of claim 1, wherein the display panel includes a light converging section provided on the panel back side of the light emitting device.

6. The display apparatus of claim 1, wherein the light emitting device includes a light emitting layer containing light emitting molecules, and a pair of electrodes opposing each other via the light emitting layer therebetween.

7. The display apparatus of claim 6, wherein one of the pair of electrodes that is provided on the panel back side is made of a transparent conductive material.

8. The display apparatus of claim 6, wherein one of the pair of electrodes that is provided on the panel back side includes an opening therein.

9. The display apparatus of claim 8, wherein the light emitting molecules contained in the light emitting layer are oriented so as to be generally parallel to a surface of the display panel on the panel back side and generally perpendicular to a straight line between the opening and the light receiving device.

10. The display apparatus of claim 8, wherein a light emitting portion of the light emitting layer is localized toward the electrode including the opening therein.

11. The display apparatus of claim 1, wherein the light emitting device is an organic electroluminescent device.

12. The display apparatus of claim 1, wherein the display panel is flexible.

13. The display apparatus of claim 1, further comprising a storage device for storing image information that is read by the light receiving device receiving light reflected by the irradiated object.

14. The display apparatus of claim 1, wherein the display apparatus has a function of displaying image information that is read by the light receiving device receiving light reflected by the irradiated object.

15. The display apparatus of claim 14, wherein the display apparatus also has a function of displaying the read image information in an inverted position.

16. An image reading/displaying system, comprising:
the display apparatus of claim 15; and
a display medium to which the image information is written by the display apparatus displaying the read image information.

17. The image reading/displaying system of claim 16, wherein the display medium includes a display medium layer, a pair of electrodes opposing each other via the display medium layer therebetween, and a photoconductive layer provided on a display medium layer side of one of the pair of electrodes.

18. The image reading/displaying system of claim 17, wherein a voltage is applied to the pair of electrodes of the display medium by using a power supplied from the display apparatus.
